(19) United States
(12) Patent Application Publication
(10) Pub. No.: US 2004/0034484 A1
(43) Pub. Date: Feb. 19, 2004

(54) Demand-response energy management system

(76) Inventors: Michael V. Solomita JR., Charlestown, MA (US); Alan Ewald, Ashby, MA (US); J. Daniell Hebert, San Francisco, CA (US); R. Benjamin Knapp, Sebastopol, CA (US); Greg McGurk, Canton, MA (US)

Correspondence Address: Brian L. Michaelis, Esq., Brown Rudnick Berlack Israels LLP, One Financial Center, Boston, MA, 02111, US

(21) Appl. No.: 10/601,399

(22) Filed: Jun. 23, 2003

Related U.S. Application Data
(60) Provisional application No. 60/391,453, filed on Jun. 24, 2002.

(51) Int. Cl. G01R 21/00

(52) U.S. Cl. 702/62

(57) ABSTRACT

A premise system that is reliable, easy to install and easy to maintain, that provides data to a computing platform detailing the energy usage of the consumer, allowing the utility company to dynamically adjust rates and output levels so as to increase cost savings. An energy management system according to the invention is designed as a network of devices installed in the home or small office to efficiently make use of heating, ventilation, and air-conditioning (“HVAC”) units and other appliances. Module devices installed on the network may communicate and transmit energy usage data to a central server, for example, located at the utility company. The utility company monitors the usage data as the data is periodically received and is able to generate messages that initiate energy saving programs specific to each premise.

### CROSS REFERENCE TO RELATED APPLICATIONS

This application claims the benefit under 35 U.S.C. §119(e) of co-pending and commonly-assigned U.S. Provisional application serial No. 60/391,453 entitled “Premise Equipment Control System and Method” filed on Jun. 24, 2002, by, which application is incorporated by reference herein.

### FIELD OF INVENTION

The present invention relates to an energy management system and particularly a cost-efficient, high functionality energy management system.

### BACKGROUND OF THE INVENTION

Nearly all homes are connected to a series of energy networks. Each home contains a utility meter, usually on the exterior of the house from which all energy used is recorded. Newer utility meters utilize Automated Meter Reading (“AMR”) technology to facilitate the reporting of energy usage data. These AMR-enabled meters broadcast data on a short range basis to a receiver carried by the utility technician. This allows the technician to gather usage data simply by being in close proximity to the AMR-enabled meters. Utility company employees record a periodic reading from these meters to determine the amount of use and the cost of the utility to be billed to the consumer. Energy management systems have become increasingly popular in the last several years due to cost concerns and environmental concerns. Before these management systems were implemented, a climate control system was governed by a temperature setting. If a threshold temperature was met or crossed by the ambient temperature, the climate-control system would initiate operation until the temperature settled back to the threshold. In a heat-providing system, if the temperature fell below the threshold setting, the heater would initiate and continue operating until the ambient temperature increased back to the set temperature. In an air conditioning system, if the temperature grew above the set threshold, the air conditioner would initiate and begin cooling the air space until the threshold temperature was met. A combination of heating and air-conditioning systems is also readily available. This type of system creates equilibrum by maintaining the temperature at the desired level at all times.

A home, however, may not need to be at the equilibrium temperature at all times. It is costly to heat or to cool a home at times when no one is present to benefit from the climate-control system. Not only does this increase costs for the consumer, but also for the utility companies. Providing unnecessary electricity and gas to homes and buildings creates an enormous strain on the utility companies and increases operating costs. An excess of wasted energy and excess strain on the utility system can lead to brownouts and create energy crises for everyone on the energy network.

Energy management systems may include a programmable thermostat that initiates signals to a heater or air conditioner at pre-determined intervals. Examples include timers that define time periods throughout the day and night when the climate-control system should be operative and maintain the set temperature. More sophisticated thermostats may include programmable parameters, such as day of the week, time, fan on/off, etc., that create multiple comfort periods based on the value of the parameters.

While these types of energy management systems have become progressively more sophisticated there still remains a gap between the utility company and the consumer preventing substantial cost savings for both parties.

Certain systems have developed whereby a home-network or premise system can be used to monitor and control climate-control devices as well as other appliances throughout the home. Microprocessors, with wired connections to the appliances and to the utility meters, interface with the appliance and serve as a management device for controlling and monitoring the appliance. A central command and control center for climate-control devices in a user-friendly setting, such as a personal computer (“PC”), facilitates the consumer's control and use over these devices, however there is no link to the utility provider itself. The utility provider must still provide the same power at constant rates and constant levels. The cost savings, if any, are only present on the consumer end of the transaction.

Known energy management systems are either very expensive and require significant rewiring of the house or are less-expensive and have a poor-reliability factor. The less-expensive systems use pre-existing wiring, however a bridge or amplifier is needed to increase signal strength. Previous systems do not provide the capability of a uniformly applicable system that requires little configuration based on the installation environment. Significant configuration differences exist in previous systems between a design for a small house compared to that of a large house or office building. Differences in PC hardware, operating systems, and related software applications can create further difficulties in installation and maintenance. The combination of varied installation environments as well as differences in control software environments can contribute to poor reliability.

Other systems have the functionality to communicate with utility companies, such as a system designed by Carrier Corporation, in partnership with Silicon Energy Corporation. The end premise system includes a thermostat and controller device. The thermostat communicates with the controller through a RF or wired connection. The utility company, through computing servers communicate to the thermostat through a bidirectional paging network. Installation of this type of system requires that the controller device be placed to optimize paging reception and transmission, often requiring installation in an attic. Application of this system is limited to premises located in strong paging network areas. A utility company, using a web-based application sends signals to the connected thermostats and changes the thermostat settings. These changes may curtail load. The thermostats may be configured to collect heating, ventilation and air conditioning (“HVAC”) run time data. The information collected is useful to determine if a demand-response event had an energy reducing effect at a particular home. The consumer uses a very limited web-based application that only allows the consumer to change, view, create and adjust the settings and schedule of the thermostat. The sole purpose of this type of system is to control the settings of the HVAC unit remotely by enabling demand-response events. These systems have limited capabilities to expand and control other devices. For example, if the utility company wanted to include water heaters in the set of demand-response assets they would have to deploy another solution into the home to control them. The utility cannot leverage the asset that has been installed in the premise, effectively limiting the return of their investment. These systems also do not provide for the collection of meter data. With no closed feedback loop, it is impossible to measure the amount of benefit gained from a demand-response event, either on a premise-by-premise basis or in aggregate. This type of system is vendor specific in that it is difficult to adapt the system to use a thermostat or controller device provided by another vendor.

Comverge, Incorporated manufactures two similar systems. One system includes one-way VHF receivers with the capability for cycling devices such as air conditioners, electric water heaters, pool and irrigation pumps and electric heat for example. The receivers are installed in close proximity to the devices they control. Utilities are able to group devices and control start times and durations to effectively generate demand-response events. This type of system offers no feedback loop making it difficult for the utility to quantify the participation and measure the success of a demand-response event.

Another system is composed of a two-way control device and module installed at the meter socket, along with the pre-existing meter, that functions as an AMR-enabled device as well as a WAN and local area network (“LAN”) connector. Connectivity between the thermostats and relay devices exist through a LAN created through CEBus power line communications. A LAN using the power lines may require a bridge and an amplifier. A WAN connection may be in the form of a broadband, fiber-optic, RF or dial-up connection. The WAN connection terminates at the module installed on the power meter. The Comverge system does provide flexibility for the utility company to directly control the thermostat. It also provides a price responsive demand response. A server gives the utility company the ability to design and monitor demand response events. The server may also collect and analyze usage data and send pricing information to the control device. The system, however, is limited to two thermostats and two other control devices. Similar to the system provided by Carrier Corporation, the other devices must be compatible with the controller offered by Comverge.

### SUMMARY OF THE INVENTION

The present invention provides a premise system that is reliable, easy to install, adapt and expand, that provides data to a computing platform detailing the energy usage of the consumer, allowing the utility company to dynamically adjust rates and output levels so as to increase cost savings. In addition the system improves operational efficiencies and allows both utilities and consumers to control energy usage, appliances, and other devices more conveniently. Through the presented system, the consumer may participate in energy management programs such as cost saving initiatives offered by the utility company. The present invention also provides a platform for additional value added services in the future.

An energy management system according to the invention is designed as a network of devices installed in the home or small office to efficiently make use of HVAC units and other appliances. Devices installed on the network may communicate and transmit information, including energy usage data to a computing platform, for example, located at the utility company. The utility company monitors the usage data as the data is periodically received and is able to generate messages that initiate demand-response events specific to each premise or to a selection or grouping of premises. The utility company uses a computing platform for the repository of data and provides access to the applications for both the utility company employees as well as the consumers. The utility company employees may interact with the computing platform via the applications to control premises, appliances, and devices, in addition to monitoring and reviewing the collected data. The consumer interacting with the application may control appliances and receive detailed energy usage and savings information. In addition to providing the utility company the opportunity to maximize efficiency and cost savings, it provides the consumer with a useful and useable manner for controlling the use of energy.

One embodiment of the energy management system contains a Local Premise Control Network (“LPCN”), on which various devices and a master controller are installed. A reliable LPCN interconnects all appliances and devices on the premise. Some devices to be installed on the LPCN are built with the necessary connectivity hardware and software to communicate. For other devices that do not contain the required hardware or software, an adapter module may be used to convert the communication protocol of the device to one that is understood by the LPCN. A Wide Area Network (“WAN”) links the premise system to the computing platform. An adapter module can be designed to create connectivity to the WAN no matter the media (e.g., broadband, POTS, Radio Frequency, pager) The LPCN may be a wireless LPCN using radio frequency (“RF”) transmission between the module devices. The LPCN is a fault-reliable network and the gateway may serve as the master controller for the network. Network protocol verifies each message sent and retransmits the message if errors are detected. If the error continues, the data to be transmitted is logged and saved for a future re-transmission and a system alert is sent to the utility company. All faults are logged by the master controller. The computing platform can then request the transmission and fault logs from the master controller as well as notify an operator at the utility company. All adapter modules are arranged and configured in a master-slave relationship. The gateway may serve as the master controller and each adapter module acts as a slave on the network.

The adapter modules are customizable units that may be added to the system. Adapter modules may include a utility meter signal receiver, hot water heater controller and WAN connector. A signal transmitter, such as an AMR-enabled device, attached to the utility meter transmits meter readings to an adapter module configured to receive data. The data is then forwarded by the adapter module across the network to the master controller via the LPCN. The master controller then forwards the data through the LPCN to the WAN adapter effectively completing the communication between the premise and the computing platform. The master controller itself transmits signals and commands to and receives logged data and other operational data from the adapter modules via the LPCN. Other modules may include such adapters as a serial adapter or a Universal Serial Bus (“USB”) adapter to be connected to other appliances. The flexibility created by the use of the adapter modules allows connectivity despite disparate protocols, physical media and distinct vendor's equipment.

In one embodiment, the consumer controls the system through the use of the gateway that manages the HVAC units and all other adapters on the premises. The gateway serves as a thermostat to the HVAC as well as the bridge for communications between the other devices and appliances on the network, such as the HVAC unit and the other adapters like the utility meter module or the WAN adapter module. The gateway designed architecture is similar to that of a typical personal digital assistant (“PDA”), however the gateway may contain resources for high-level software development. The gateway has a large liquid-crystal-display (“LCD”) for displaying a browser-like interface for complex user interactions and experiences. It also contains a standards based operating system that includes developer support for integration with standard information technology (“IT”) system development tools and for dynamic software libraries. The gateway may be a commercially available PDA, such as the Compaq IPAQ or the Sharp Zaurus. The operating systems on these commercially available PDAs may be a Windows Pocket PC on the IPAQ or a Linux based system on the Zaurus. Alternatively the gateway may be in the form of a set-top box running a Linux based operating system. A programmable microcontroller thermostat is used in conjunction with these forms of the gateway, such as the Honeywell Enviracom thermostat. In conjunction with the thermostat hardware, the gateway also mimics all functions normally associated with a traditional thermostat for HVAC units. The gateway may be directly connected to existing HVAC unit controls as well as a temperature sensor using the pre-existing thermostat wires.

The gateway contains sophisticated software applications to monitor and control the adapter modules on the LPCN as well as log and transmit data across the LPCN to the WAN adapter and out to the computing platform. The gateway logs time, temperature readings, measurements and status data from all LPCN modules. It may also log LPCN fault information and unexpected results and changes to system configuration data. The gateway may also manage control signals and messages for the HVAC unit. The gateway provides the user interface and manages the physical LCD screen, records and timestamps all sensor data, and all system state changes.

The energy management system presented provides a link to the utility company through the WAN adapter module. The WAN adapter module may be built to utilize any form of data communication media, such as broadband, POTS, RF, two-way paging for example. The link is used to transmit usage data from the gateway to the computing platform. The computing platform, through automated processes or through the direction of an operator may issue messages to the gateway designed to maximize efficiency and cost savings. The link also provides a mechanism for the utility company to upload new applications and diagnostic tools onto the gateway for maintenance and repair. When an error log is transmitted to the server, the server notifies an operator from the utility company, either through a user-interface at a workstation or a two-way messaging device, such as a pager or a mobile phone. The operator may then request more diagnostic data from the gateway or upload new applications to rectify the fault with no inconvenience to the consumer.

The premise system is advantageous over previous systems because installation of the system is easy and less expensive than that of previous systems without sacrificing reliability. The system is easily adaptable to all premise environments and allows for easy expansion of the system. If a wireless LPCN RF transmission is implemented, there are no wires needed to connect adapter modules. There is also a great degree of freedom in the location of the modular devices making the ease of installation greater. Repeater or relay adapter modules may be implemented to increase connectivity across larger areas.

Yet another advantageous feature of the presented system is the fault-reliable network used for the LPCN and inter-module communication. When erroneous messages are transmitted, or a message is not received, the master controller will repeat the transmission or log the messages to be sent until a future time, when a connection is re-established. These precautions make the system more reliable and more robust than previous systems.

Another advantageous feature of the current invention over previous systems is the independence from using a pre-existing PC-based gateway. There is no overlap of energy management applications with other applications a home PC might contain. This prevents the misallocation of computing resources in the gateway at critical times. Applications that share resources are more likely to fail than those that have entirely dedicated and independent resources. This independence also facilitates maintenance and installation. In previous systems, repairing one application without disrupting valuable computing resources already allocated is a difficult and costly task.

### BRIEF DESCRIPTION OF THE DRAWINGS

The foregoing and other features and advantages of the present invention will be more fully understood from the following detailed description of illustrative embodiments, taken in conjunction with the accompanying drawings in which:

FIG. 1 depicts a system-wide diagram of a particular embodiment of the energy management system.

FIG. 2 is a high-level schematic diagram of a particular embodiment of the energy management system.

FIG. 3 is an architecture diagram of a RN module in accordance with an embodiment of the present invention.

FIG. 4 is a diagram of the major components of the gateway software in accordance with an embodiment of the present invention.

FIG. 5 depicts the application user interface component of the gateway software in accordance with an embodiment of the present invention.

FIG. 6 is a diagram of the main application process component of the gateway software in accordance with an embodiment of the present invention.

FIG. 7 is a diagram of the application infrastructure library component of the gateway software in accordance with an embodiment of the present invention.

FIG. 8 is a diagram of the watchdog process component of the gateway software in accordance with an embodiment of the present invention.

FIG. 9 is an architecture diagram of the reliable network communications library.

FIG. 10 is an architecture diagram of the thermostat hardware interface of the gateway application.

FIG. 11 is an architecture diagram of the gateway hardware in accordance with an embodiment of the present invention.

FIG. 12 is a front view of the gateway in open mode in accordance with an embodiment of the present invention.

FIG. 13 is a front view of the gateway in closed mode in accordance with an embodiment of the present invention.

FIG. 14 depicts an alternative embodiment of the energy management system in which the gateway serves as a slave to a home-gateway master controller.

### DETAILED DESCRIPTION

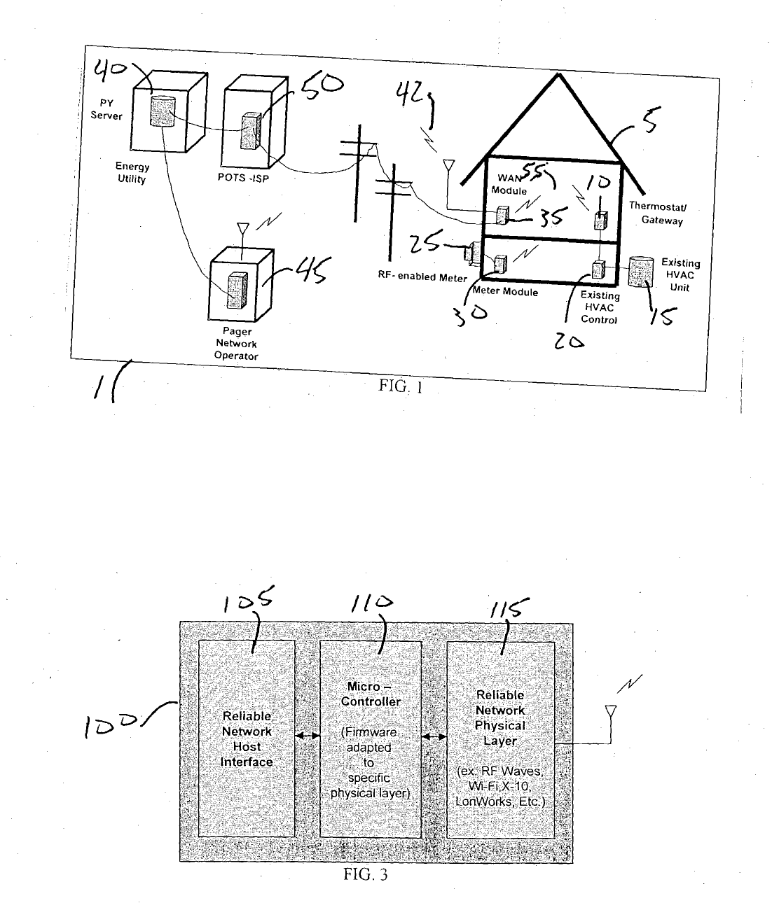

FIG. 1 depicts a system architecture detailing an embodiment of an energy management system 1. A home or office 5 is shown containing a gateway 10, a HVAC unit 15 connected to HVAC controls 20, a utility meter 25, a utility meter reading adapter module 30 and a WAN adapter module 35. The energy management system 1 sends and receives signals, messages, commands, and data to energy company servers 40 through a two-way pager network 42 or a modem/broadband connection 50.

In one embodiment, the gateway 10 serves as a master controller for the adapter modules 30, 35 located on a reliable network (“RN”) 55. The gateway 10 transmits and receives RF signals across the RN 55 to and from the adapter modules 30, 35. The gateway 10 issues commands to the adapter modules 30, 35 based on data received from other adapter modules 30, 35. The gateway 10 also functions as a micro-controller based thermostat for the HVAC unit 15 over the pre-existing HVAC controls 20 by mimicking the functionality of a typical programmable thermostat. The gateway is capable of responding to demand/response commands sent from computing platforms 40. The gateway 10 logs data, transmitted from the adapter modules 30, 35 as well as data from the thermostat function that may then be uploaded to the computing platforms 40 at specific time intervals. Usage data may include, but is not limited to temperature, thermostat settings and user input commands.

The utility meter 25 is connected, as a device, to the utility meter adapter module 30. In this embodiment, the utility meter reading adapter module 30 is designed to work with several pre-existing models of AMR-enabled utility meters. Examples include, but are not limited to an AMR-enabled Schlumberger meter or an AMR-enabled General Electric meter. The utility meter adaptor module 30 can be configured to function with utility meters using differing AMR-enabling technologies. The utility meter adapter module 30 broadcasts RF signals containing electricity usage data output by the AMR-enabled utility meter 25 through the RN 55 to the gateway 10.

The WAN adapter module 35 serves as a link between the gateway 10 via the RN 55 and the computing platforms 40. The WAN adapter module 35 may consist of a dial-up modem/broadband connection 50 or a two-way pager network 42 connection as a conduit between the computing platforms 40 and the gateway 10. A pager network operator 45 receives and transmits signals from the WAN adapter module 35 and the computing platforms 40. The computing platforms 40 log and evaluate data transmitted from the RN 55 allowing for dynamic and efficient output of energy resources.

Data from the energy management system 1 may be uploaded to the computing platforms 40. This allows the utility company, through its servers 40 to monitor and evaluate the incoming data sent from the energy management system 1 through the WAN 37. The data transmitted is then used to revise the energy management scheme at a system-wide level or at a premise-by-premise level. The computing platforms 40 then respond by transmitting signals that initiate cost-saving programs specific to each premise. The computing platforms 40 may also dynamically load software packages and drivers to the adaptor modules 30, 35 over the WAN 37 through the WAN adapter module 35 and the RN 55. This facilitates maintaining and updating the energy management system software resident on the adapter modules 30, 35 from both a time and cost perspective.

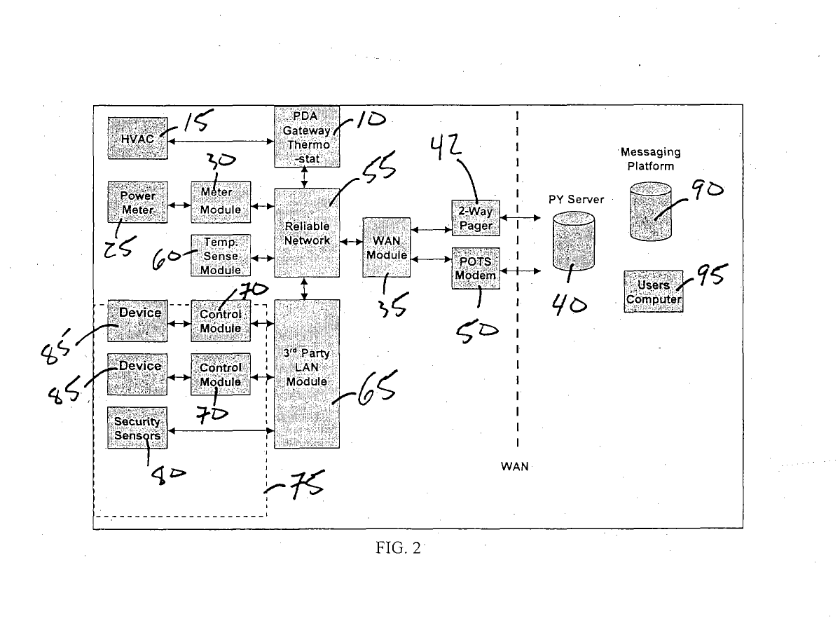

FIG. 2 is a high-level component diagram of one embodiment of the energy management system 1. The RN 55 provides for communication between the gateway 10, the utility meter reading adapter module 30, a temperature sensor adapter module 60, a third-party LAN adapter module 65 and a WAN adapter module 35. The adaptor modules 30, 35, 65 link devices and other networks to the RN 55 of the energy management system 1.

The gateway 10 serves as both the micro-controller based thermostat and as the master controller for the adapter modules 30, 35, 65 on the RN 55. The gateway 10 is the main user-interface in the home to the energy management system 1 and is capable of controlling appliances and devices 85 located on the RN 55. The HVAC unit 15 is connected to the gateway 10. The gateway 10 serves as a traditional programmable thermostat. The user inputs commands and program settings into the gateway 10. The gateway 10 transmits the commands to the HVAC unit 15 and the HVAC unit 15 responds by changing its mode of operation. The gateway 10 may also transmit commands to the adapter modules 30, 35, 65 which, in turn, forward the commands to the appliances, devices. The gateway 10 receives data from the adaptor modules 30, 35, 65 and stores the data for periodic upload to the computing platforms 40.

The third-party LAN adapter module 65 provides a link from the RN 55 to another third party LAN 75. The third-party LAN adapter module 65 allows communication between a distinct network (e.g. networked sensors) 80 and other adapter modules 30, 35, 65 that reside on the RN 55. The third-party LAN 75 may consist of a home security system, or a home management or automation network. The gateway 10 can control and monitor, through the third-party LAN adapter module 65, the other network 80 and appliances and devices 85. The third-party LAN adapter module creates a single-point monitor and control device for the other network 80 and appliances and devices 85. The third-party networks 75 typically consist of control modules 70 connected to the appliances and the devices 85, such as HVAC units, lights, or security sensors.

The utility meter adapter module 30 takes the output of the AMR-enabled utility meter 25 and transmits RF signals containing electricity usage data to the RN 55. The gateway 10 receives and stores the usage data until it is uploaded to the computing platforms 40. The data transmitted to the computing platforms 40 allows the utility company to dynamically revise its energy resources and outputs based on the level of energy used and the strain on the system created by each energy consumer.

The temperature sensor adapter module 60 monitors and transmits an ambient temperature to the gateway 10 via the RN 55. As with a conventional HVAC configuration, the temperature reported by the sensor 60 and the temperature threshold setting stored by the user through the thermostat function of the gateway 10 determines the HVAC unit's 15 state of operation. The gateway 10, acting as a thermostat, compares the data reported by the temperature sensor 60 with the temperature threshold to determine the mode of operation of the HVAC unit 15.

The WAN adapter module 35 is a link between the gateway 10 and the computing platforms 40 using a 2-way pager network 42 or a dial-up modem/broadband connection 50 as means for connecting the two. Other media are also available to provide a connection to the computing platform, such as POTS, RF and digital cellular networks. The computing platforms 40, using sophisticated algorithms and software tools, analyze the uploaded data from the energy management system 1. The platform operator may issue messages and commands pertaining to energy savings and cost savings programs through the WAN 37, using the WAN connection 50 or two-way pager network 42, to the gateway 10 via the RN 55.

In one embodiment, the gateway 10 serves as the master device on the RN 55 and the adapter modules 30, 35, 65 serve as slaves receiving commands from the gateway 10. During initialization the adapter modules 30, 35, 65 broadcast identifications (“IDs”) and the gateway 10 receives and stores the IDs in memory. Thereafter, the gateway 10 communicates with adapter modules 30, 35, 65 from which IDs have been received during initialization. The gateway 10 also detects faults and outages of the adapter modules 30, 35, 65.

The RN 55 is designed as a fault-reliable network. The gateway 10, serving as master controller, audits communications using CRC or equivalent techniques and issues retransmit commands if there are errors or faults in the RN 55. If the fault persists, the data is logged by the slave adapter module 30, 35, 65 for future re-transmission. The gateway 10, serving as the master controller logs all faults and attempts to retransmit at periodic intervals. If a fault condition persists a system alert is issued by the gateway 10 to the computing platforms 40. The sophisticated software of the computing platforms 40 can then evaluate the fault and initiate a course of action.

Referring to FIG. 3, each adapter module on the RN 55 contains a RN module 100. The RN module 100 allows the adapter module to communicate across the RN 55 to the master-controller and other devices. The RN 55 is configured as a master-slave network. The firmware installed on the adapter modules dictates the device's role as a master or a slave. A reliable network host interface 105 communicates high-level functions to the gateway 10 or adapter modules 30, 35, 65. A micro-controller 110 implements a RN stack and communicates with a RN physical layer 115. The RN physical layer 115 may be, for example, a radio frequency network or power line systems. In one embodiment, a radio frequency emitting chipset, such as one from RFWaves, is used. The RFWaves chipset provides a low-cost, 2.4 GhZ world-wide license free band frequency, a raw data rate of up to 1 Mbps and offers versatile operation voltages and communication ranges. The RF chipset has low power consumption, a simple module architecture with minimal external components and provides for a standard encrypted query protocol. The RF chipset is a cost effective and efficient solution for the RN physical layer 115 that connects the gateway 10 and the adapter modules 30, 35, 65.

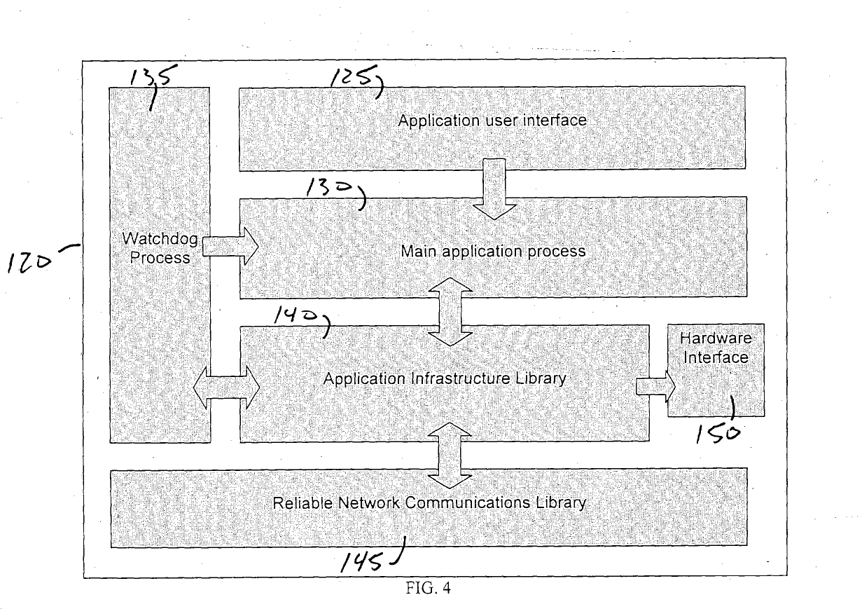

With respect to FIG. 4, the software application 120 architecture of the gateway 10, designed around a PDA, is built for the interaction of several major components. The application user interface 125 sends commands to the main application process 130. The main application process 130 sends and receives data from a watchdog process 135, that monitors the application process, and the application infrastructure library 140 which supports the main application process 130 with various lower level functions.

The reliable network communications library 145 provides an interface for the main application process 130 and the watchdog process 135 via the application infrastructure library 140 to communicate with devices in the RN 55 or the WAN. The reliable network communications library 145 is linked with the application infrastructure library 140 and provides a low-level interface for formatting messages for a delivery to and from the RN 55. The reliable network communications library 145 also monitors the RN 55 for error conditions. If an error is detected, the reliable network communications library 145 transmits a message to the event logger in the main application process 130. The hardware interface 150 is implemented as a library that is linked to the application infrastructure library 140. The hardware interface 150 enables the gateway software 120 to send and receive data from the thermostat hardware, such as temperature sensors and the HVAC controls 20.

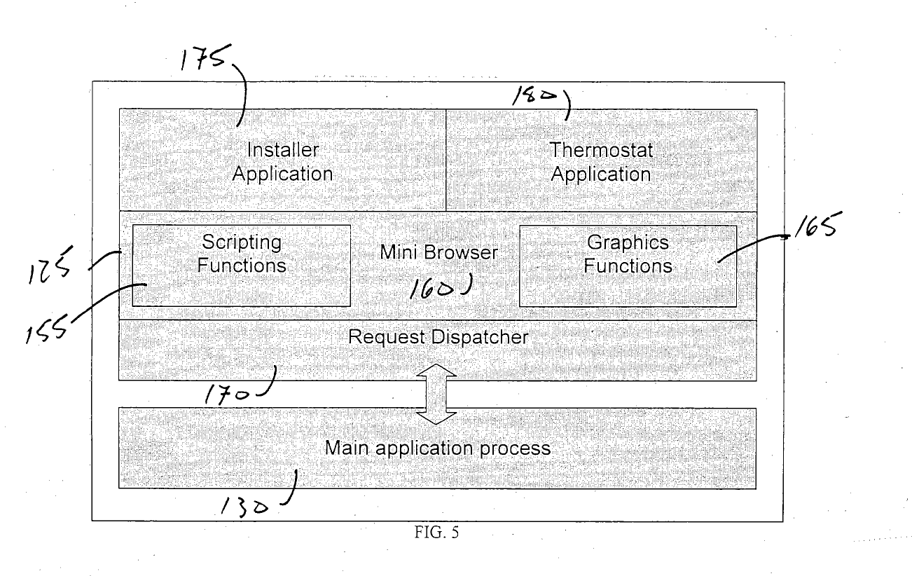

Regarding FIG. 5, the application user interface 125 controls the user interactions with the gateway software 120 including information formatted and displayed on the LCD screen, and user input retrieved from physical switches. The application user interface 125 includes simple scripting and validation functions 155 as well as a mechanism to send commands to the main application process 130. The application user interface 125 is implemented as a mini-browser 160 with application screens implemented as pages. The mini-browser 160 formats applications for display and captures user input. The scripting functions 155 implement dynamic content display in the application and validate user input. The graphics functions 165 render graphical information to the LCD screen.

The request dispatcher 170 sends commands to the main application process 130 as a result of user input and delivers the response from the main application process 130 to the user interface. The installer application 175 includes the application screens or pages that implement the initial installation and setup steps, and subsequent installation and setup steps for future devices or adapter modules, required to configure the gateway 10. The application user interface 125, through the main application process 130, discovers the available devices on the RN 55, downloads information from the computing platforms 40 and stores configuration settings. The thermostat application 180 includes the application screens or pages that implement the interface between the user and the energy management system 1. It relies on the main application process 130 to respond to commands to control or read the thermostat hardware and to initiate actions on other devices in the RN 55.

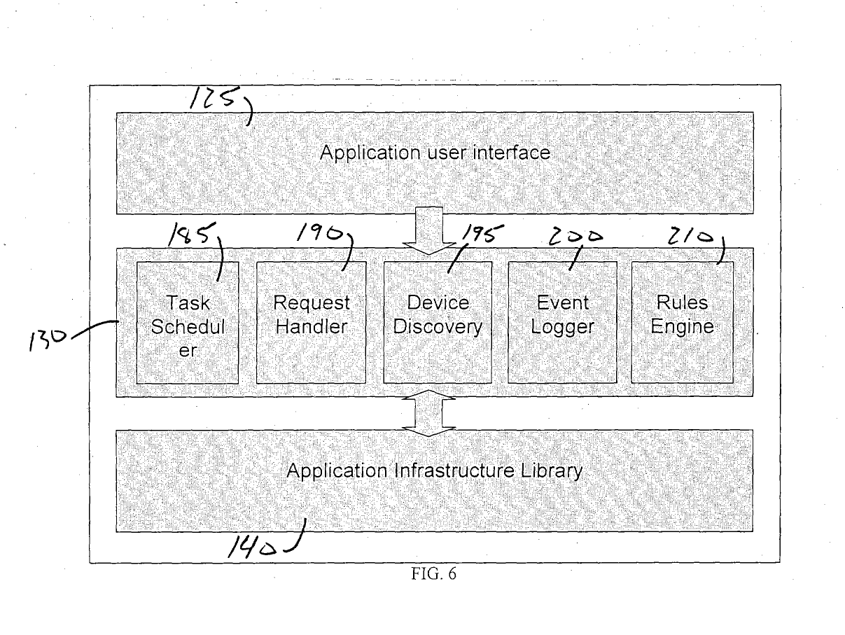

Referring to FIG. 6, the main application process 130 is composed of sub-components that may include a task scheduler 185, a request handler 190, a device discovery sub-component 195, an event logger 200, and a rules engine 210. The task scheduler 185 stores data concerning events scheduled to execute in the future, for example, at a pre-defined time, the task scheduler 185 initiates an event sending a control signal to a device. The request handler 190 responds to requests received from the application user interface 125 or the computing platforms 40. The device discovery sub-component 195 searches for devices connected to the RN 55 by sending messages and storing the responses to persistent storage. The event logger 200 listens for and stores events that occur on the RN 55, such as faults and state changes. The event logger 200 also logs events received from the thermostat hardware.

The rules engine 210 monitors the event logger 200 for specific events and initiates subsequent actions when pre-defined rules are satisfied. Examples of rules and actions defined in the rules engine include, but are not limited to: if there is no motion detected in a room for 30 minutes, turn off the lights in that room; if the efficiency of an oil burner falls outside of defined parameters, send a message to the energy management service to schedule service; if the utility meter has not reported data in two hours, then transmit a message to the energy management system to schedule service; if a compressor is running and only has a short time remaining in its cycle and a second compressor is about to begin running, delay the second compressor until the first compressor cycle is complete; if the weather forecast indicates a high temperature, schedule an energy management event to raise the indoor temperature at which the air conditioner begins cooling; if the current price of energy is peaking, reduce power consumption of all devices to a pre-defined threshold; if the humidity in a room falls below a pre-defined parameter, turn on the humidifier. The rules can be defined to include several different parameters. The task scheduler 185, the request handler 190, and the rules engine 210 all rely on the other sub-components of the main application process 130. The sub-components of the main application process 130 rely on the application infrastructure library 140 to complete their functions, such as communications, persistence, and message protocol translation.

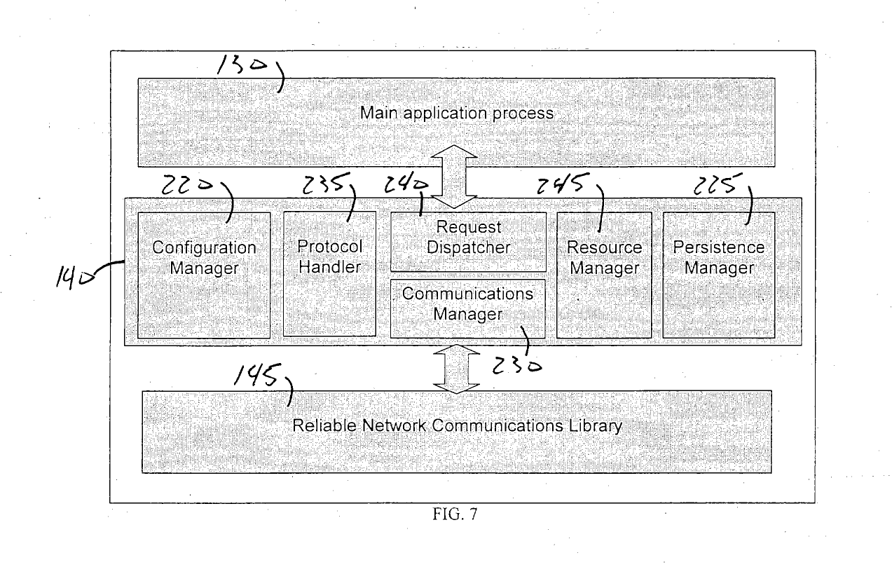

Referring to FIG. 7, the application infrastructure library 140 supports the main application process 130 with lower level functions such as configuration management, message protocol resource management, persistent storage and network communications. The reliable network communications library 145 provides an interface for the application infrastructure library 140 to communicate with devices on the RN 55.

A configuration manager 220 controls all configuration information for the gateway application 120. The gateway configuration may be changed through a variety of methods, including through the installation application, the rules engine 210, or remotely from the computing platforms 40. The configuration manager 220 relies on the persistence manager 225 to store configuration information. It also uses the communications manager 230 to communicate with computing platforms 40 or with other devices on the RN 55. The protocol handler 235 stores definitions of message formats that are understood by the devices on the RN 55. The protocol handler 235 completes all translations required to forward messages from one device to another. The request dispatcher sends commands to the main application process 130 as a result of messages received from the devices on the RN 55 or from the computing platforms 40. The request dispatcher 240 uses the communications manager 230 to interface with the RN 55.

The communications manager 230 converts messages from the main application process 130 or the watchdog process 135 into messages that are understood by the RN 55. The resource-manager 245 monitors and controls any PDA operating system resources that are needed by the gateway application 120. If a resource is low, it can gather any un-used or low-priority resources to avoid a system failure. The resource manager 245 operates in conjunction with the persistence manager 225 to supervise memory and non-volatile storage. The persistence manager 225 stores and retrieves data from non-volatile storage.

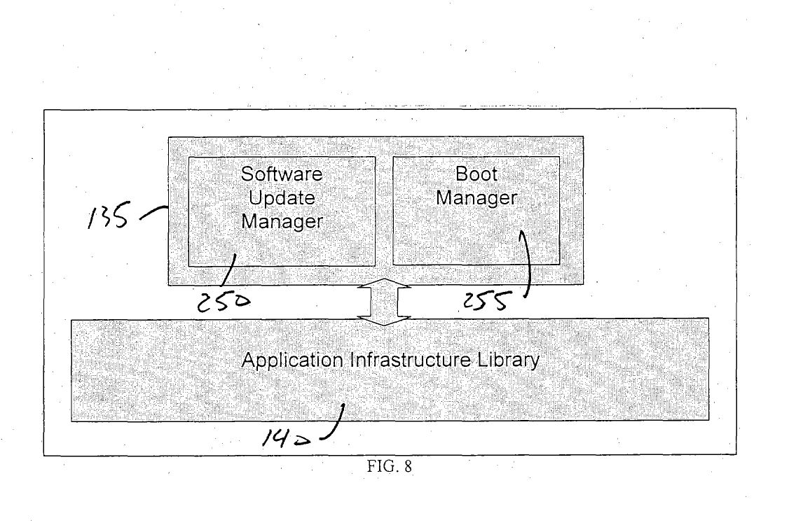

Regarding FIG. 8, the watchdog process 135 may be implemented as a separate task, separate threads or a separate process based on the capabilities of the PDA Operating System. The software update manager 250 may receive periodic messages from the computing platforms 40 detailing updates to the gateway application software 120. It installs the updates and schedules an application reboot using a boot manager 255. The software update manager 250 uses the application infrastructure library 140 for communications and persistence. The boot manager 255 monitors the main application process 130 to ensure that the main application process 130 is not online. If the boot manager 255 detects the main application process 130 is available or a system fault has occurred, the boot manager 255 reboots the gateway application 120 or the entire gateway 10.

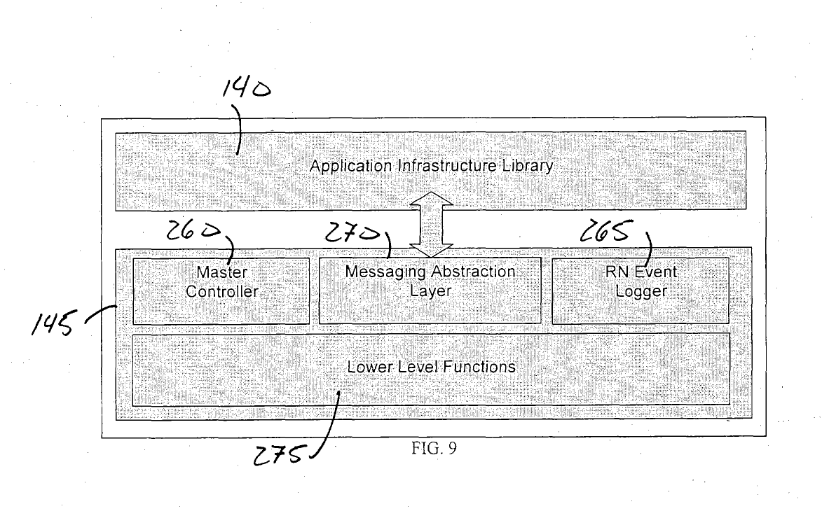

Referring to FIG. 9, the reliable network communications library 145 is implemented as a separate library that is linked with the application infrastructure library 140. The subcomponents of the reliable network communications library include a master controller 260, a RN event logger 265, a messaging abstraction layer 270, and a collection of low-level functions 275. A master controller sub-component 260 monitors the RN 55 for error conditions and devices with which it can communicate. If a RN error is detected the RN event logger 265 forms a message to be dispatched to the event logger 200 in the main application process 130. A messaging abstraction layer 270 provides an abstract interface for formatting, sending and receiving messages on the reliable network 55 and for using the reliable network's 55 protocol. The communications manager 230 of the application infrastructure library 140 uses the messaging abstraction layer 270 to send and receive application level messages on the RN 55.

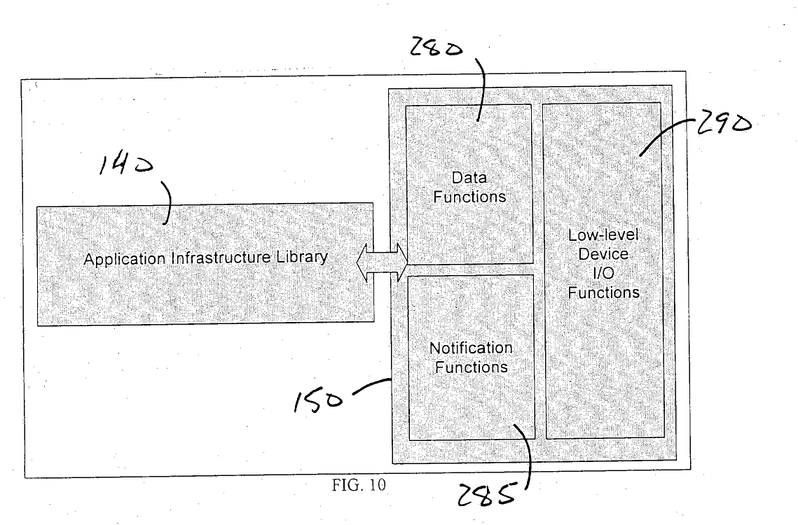

Regarding FIG. 10, the hardware interface component of the gateway application 120 is implemented as a separate library that is linked with the application infrastructure library 140. The hardware interface 150 enables the gateway application 120 to interact with temperature sensors 60 and the HVAC controls 20 directly connected to the gateway in this embodiment. The data functions sub-component 280 enables the gateway application 120 to change data values in the thermostat or HVAC controller hardware such as heat and cool setpoints or schedule times. The notification functions sub-component 285 provides updates from the thermostat or HVAC controller hardware about changes in the hardware state, data measured by temperature sensors, or hardware faults detected. The low-level device I/O functions subcomponent 290 sends and receives instructions and data to and from the thermostat and HVAC controller hardware via serial communications, by manipulating hardware registers, or other similar means

Referring to FIG. 11, the gateway 10 is designed around a PDA architecture with added functionalities, such as a thermostat function for controlling the HVAC unit 15. The gateway hardware extends the PDA 300 through additional interface hardware 305 such as an HVAC controller 310, a temperature sensor 315 and a RN module 100. The HVAC controller 310 implements a universal interface to a range of possible HVAC control situations including common control types such as various heat pumps and multizone HVAC control. The resultant gateway 10 is a PDA that has specific hardware features enabling both thermostat and gateway application 120 functions. This device replaces the pre-existing thermostat.

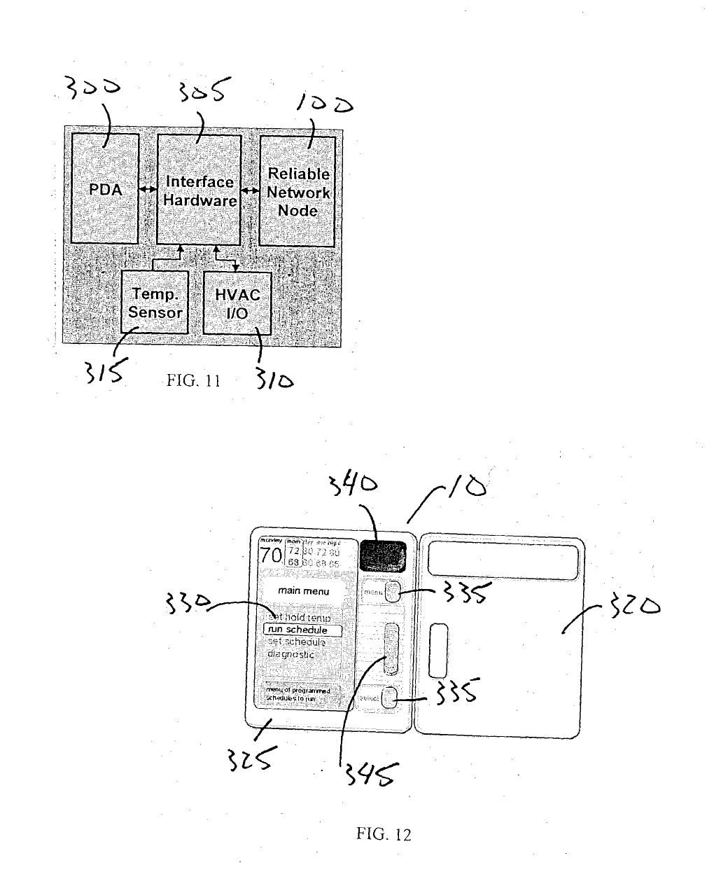

Referring to FIG. 12, an embodiment of the gateway 10 in open mode is shown with a hinged cover 320 fully open. The gateway 10 contains a faceplate 325 having openings for a LCD screen 330, operation buttons 335, a message indicator 340 and a jog-dial 345. The LCD screen 320 displays configuration and status information of the energy management system 1 to the user in a browser-like interface. In open mode, the LCD screen 330 displays in-depth menus for schedule programming, diagnostics, and several other functionalities. The gateway 10 contains resources to support high level software development. The gateway 10 utilizes a well-supported standards-based operating system that includes developer support for integration with standard IT system development tools and support for dynamic software libraries. The operation buttons 335 are a means for a user to navigate and input commands highlighted on the LCD screen 330. The jog-dial 345 allows the user to navigate through menus and options as a means of controlling and monitoring the energy management system 1. The hinged cover 320 of the gateway has openings aligned with critical display areas of the LCD screen 330 as well as an opening for the jog-dial 345 to allow for operation of the thermostat functions of the gateway 10 while the hinged cover 320 remains closed.

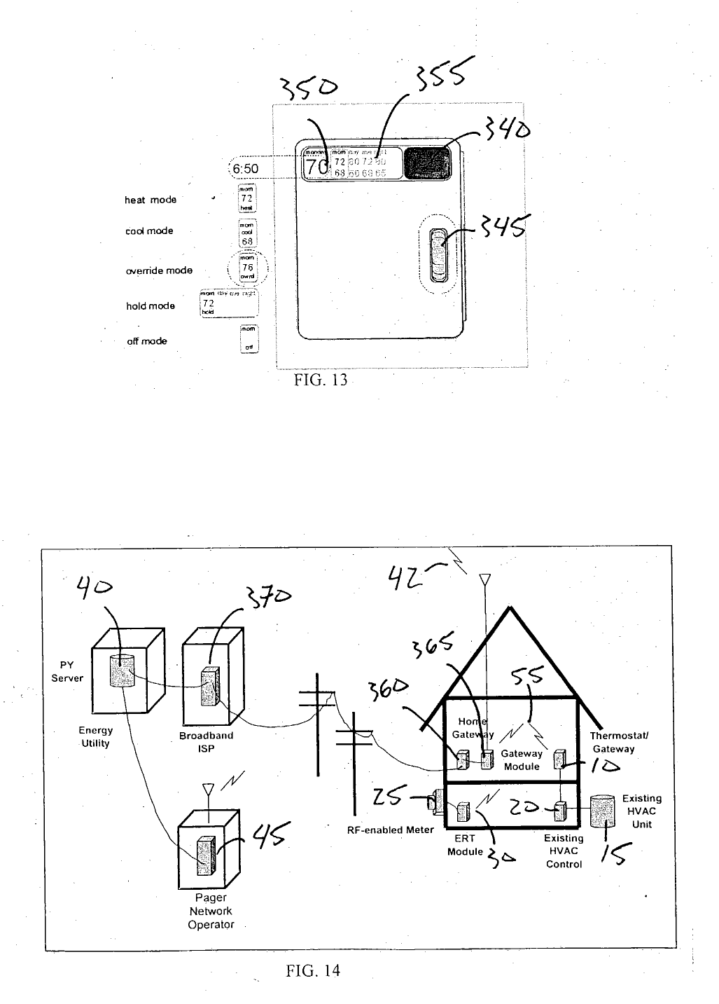

Referring to FIG. 13, the front-cover obscures a large portion of the LCD screen 330. In closed mode, the gateway 10 operates as a traditional thermostat. The user adjusts the heating or cooling temperature by rotating the jog-dial 345 until the desired temperature setting is reached. Rotating the jog-dial 345 will interrupt and override any pre-programmed setting of the gateway 10. In an embodiment, the exposed portion of the LCD screen 350 alternately displays the current temperature and current time. Also visible in closed mode is the schedule 355 of heat and cool threshold temperatures for pre-programmed periods such as wake, leave, return and sleep. The gateway 10 may also notify the user, by an audible and visual notification, that a message has been received from the computing platforms. The message indicator 340 will light up upon receiving a message. A range of customizable audible and visible notifications may be implemented depending on the importance or severity of the message. Less urgent messages may use a softer tone or display, for example.

In an alternative embodiment, as depicted in FIG. 14, a home-gateway 360 is the master controller on the RN 55 and replaces the WAN adapter module 35. The home-gateway 360 is connected to a home-gateway adapter module 365. The home-gateway adapter module 365 transmits and receives signals across the RN 55 to the gateway 10 and adapter modules 30, 365. The gateway 10 is a slave device in this configuration acting as the thermostat. The home-gateway adapter module 365 is linked to the computing platforms 40 through a bi-directional broadband ISP connection 370. A two-way pager network 42 may be used for redundancy and reliability if the broadband connection 370 fails. A pager network operator 45 receives and transmits signals from the home-gateway adapter module 365 and the computing platforms 40.

Although the embodiments described herein discuss thermostat, gateway and master controller functionality, it should be appreciated by those skilled in the art that such functionality can be provided in a system according to the invention with separate and distinct functional elements (i.e. a separate thermostat, separate gateway and separate master controller), or such functionality can be implemented by combining these elements (e.g. thermostat and gateway functionality in a discrete component with or without the master control functionality, or the gateway and thermostat as separate components with one or the other including the master controller).

Although the embodiments described herein discuss a gateway and a master controller that may emulate the functionality of a wall-mounted thermostat, it should be appreciated by those skilled in the art that the gateway or master controller may be a mobile device, such as a commercial hand-held PDA, for example the Compaq IPAQ, or the Sharp Zaurus. The gateway or master controller may also be a detachable wall unit, capable of monitoring and controlling the system while being carried by a user or technician.

Although the embodiments described herein discuss an energy management system targeted to utility company services, it should be appreciated by those skilled in the art that the services may include other utility systems, (e.g. water services, sewage services, gas services or electricity services), or other command and control systems (e.g. pool monitoring systems, asset performance monitoring services).

Although the embodiments described herein discuss networks utilizing specific media protocols such as RF, dial-up modem, POTS, two-way paging and broadband, it should be appreciated by those skilled in the art that the media of the WAN connection or the RN may include other forms of media (e.g. power lines, RF, dial-up modem, POTS, two-way paging, broadband, digital wireless broadband, and any hybrid combination thereof).

It should be apparent to those skilled in the art that many other combinations and configurations of the above mentioned details and embodiments are possible without departing from the true underlying principles of the invention.

What is claimed is:

1. A utility consumption control network system for controlling consumption of units of a resource provided by a utility, comprising:
a communications network accessible by the utility;
a gateway connecting to the communications network, including,
an operating system;
a user interface;
at least one application transmitting and receiving data through the utility consumption control network, processing the data and providing the data to the user interface;
a user interface control mechanism selecting portions of the user interface;
a device in communication with the utility consumption control network, the device consuming units of the resource provided by the utility; and
an adapter in communication with the device, translating data sent to and from the device on the communications network into a protocol for communication with the gateway.

2. The utility consumption control network system of claim 1 further comprising:
a utility meter configured for automated reading; and
a utility meter adapter in communication with the utility meter, translating a signal containing usage data from the utility meter and transmitting the usage data to the gateway.

3. The utility consumption control network system of claim 1, wherein the gateway is connected to a wide area network to provide access by the utility.

4. The utility consumption control network system of claim 3, further comprising:
a computing platform operatively connected to the wide area network, the gateway configured to send and receive data through the wide area network from the computing platform.

5. The utility consumption control network system of claim 1 wherein the user interface is a graphical user interface.

6. The utility consumption control network system of claim 5 wherein the user interface control mechanism is at least one input button selecting menus for the graphical user interface.

7. The utility consumption control network system of claim 1 wherein, the device is a thermostat in communication with a climate control unit, and the thermostat is in communication with the communications network, whereby the thermostat transmits temperature data to the gateway and receives command signals from the gateway.

8. The utility consumption control network system of claim 1 wherein,
the gateway further includes a thermostat for monitoring an ambient temperature data, and the thermostat is in communication with a climate control unit, whereby the gateway transmits commands to the climate control unit.

9. The utility consumption control network system of claim 1 further comprising:
a thermostat reporting and monitoring temperatures; and
a climate control unit, in communication with the thermostat, treating an ambient airspace.

10. The utility consumption control network system of claim 9 wherein the climate control unit treats the ambient airspace by at least one of heating, cooling and humidifying/dehumidifying.

11. The utility consumption control network system of claim 1 wherein the resource provided by the utility is at least one of electric, water and gas.
